(19) United States
(12) Patent Application Publication
(10) Pub. No.: US 2008/0096044 A1
(43) Pub. Date: Apr. 24, 2008

(54) Plating Method, Electrically Conductive Film And Light-Transmitting Electromagnetic Wave Shielding Film

(76) Inventor: Jun Matsumoto, Kanagawa (JP)

Correspondence Address: BUCHANAN, INGERSOLL & ROONEY PC, POST OFFICE BOX 1404, ALEXANDRIA, VA, 22313-1404, US

(21) Appl. No.: 11/794,351

(22) PCT Filed: Jun. 2, 2006
(86) PCT No.: PCT/JP06/11568

§ 371 Date: Jun. 28, 2007

(30) Foreign Application Priority Data
Jun. 3, 2005 (JP) 2005-164470

(51) Int. Cl. C25D 3/38; C25D 5/56; G02B 1/10; H01B 13/00; H01B 5/14; H05K 9/00

(52) U.S. Cl. 428/623; 205/102; 205/93

(57) ABSTRACT

A plating method comprising: continuously electroplating a film having a surface resistance of 1 to 1,000 ohms per square, wherein a plating solution has a copper content of 150 to 300 g/l as expressed by weight of copper sulfate pentahydrate.

### TECHNICAL FIELD

The present invention relates to a plating method, an electrically conductive film and a light-transmitting electromagnetic wave shielding film.

### BACKGROUND ART

There has recently been a demand for the development of technology for forming an electrically conductive thin metal film on an insulator film, such as an electromagnetic wave shielding film used for a flexible wiring board or a plasma display in an electronic or like apparatus.

For example, JP-A-2004-221564 discloses a method of manufacturing an electromagnetic wave shielding film by exposing and developing a photosensitive material containing a silver salt. According to JP-A-2004-221564, the method disclosed therein can form a pattern of fine lines accurately and make an electromagnetic wave shielding film of high quality and transparency at a low cost on a mass-production basis.

### DISCLOSURE OF THE INVENTION

When an electromagnetic wave shielding film is made by employing the technique described in JP-A-2004-221564, developed silver formed by the exposure and development of a photosensitive material has to be plated with a thick metal film to provide a high electromagnetic wave shielding property.

It is usually preferable from the standpoints of productivity, cost and easy thickness control to employ electroplating to form a thick metal film, but as no direct electroplating is possible on an insulator film having a high surface resistance like a film formed according to JP-A-2004-221564, it is usual practice to form a thin metal film on an insulator film by e.g. sputtering, vacuum vapor deposition or electroless plating and then employ electro-plating to achieve an intended film thickness. Electroless plating is, however, required to realize a surface resistance of 1 ohm/square or less before electroplating, and requires a great deal of time to do so, or when sputtering is employed, it is possible only at a lower line speed. These and other factors have been detrimental to productivity.

According to JP-A-2004-221564, electroplating is performed on a sheet-feed and batch basis. When a film having a surface resistance as high as 1 ohm/square or more is electroplated on a sheet-feed basis, a film portion in contact with a plating solution is plated with a greater thickness in an area closer to the source of an electric current. This phenomenon is outstanding at the start of plating, or when an electric current is fed for the first time, and it has been found that uniform plating is difficult even if plating is continued.

In view of the problems as pointed out above, it is an object of the present invention to provide a plating method of high productivity which can plate even a film having a high surface resistance uniformly.

It is another object of the present invention to provide a uniformly plated electrically conductive film and a light-transmitting electromagnetic wave shielding film.

The above problems are solved by the invention as set forth below.

(1) A plating method comprising:

continuously electroplating a film having a surface resistance of 1 to 1,000 ohms per square, wherein a plating solution has a copper content of 150 to 300 g/l as expressed by weight of copper sulfate pentahydrate.

(2) The plating method as described in (1) above,

wherein the plating solution comprises a sulfur compound.

(3) The plating method as described in (1) or (2) above,

wherein the plating solution comprises a nitrogen compound.

(4) The plating method as described in any of (1) to (3) above,

wherein the plating solution comprises a polymer.

(5) The plating method as described in any of (1) to (4) above,

wherein the film has a pattern formed with a silver mesh.

(6) The plating method as described in (5) above,

wherein the silver mesh is formed from a developed silver.

(7) The electrically conductive film produced by a method including a plating method as described in any of (1) to (6) above.

(8) A light-transmitting electromagnetic wave shielding film comprising an electrically conductive film as described in (7) above.

(9) An optical filter comprising:

a light-transmitting electromagnetic wave shielding film as described in (8) above; and

an adhesive layer.

(10) The optical filter as described in (9) above, which further comprises a peelable protective film.

(11) The optical filter as described in (9) or (10) above, which further comprises a functional layer having at least one function selected from infrared blocking, hard coating, antireflective, antiglare, antistatic, anti-staining, ultraviolet blocking, gas barrier and display panel damage preventing.

(12) The optical filter as described in (9) or (10) above, which has an infrared blocking property.

### BRIEF DESCRIPTION OF THE DRAWING

FIG. 1 is a schematic diagram illustrating an exemplary embodiment of an electroplating tank which is suitable for use with the plating method of the present invention,

wherein 10 denotes an electroplating tank; 12a and 12b denote current feed rollers; 13 denotes an anode plate; and 16 denotes a film.

### BEST MODE FOR CARRYING OUT THE INVENTION

A mode of carrying out the plating method according to the present invention will now be described with reference to a drawing. A plating apparatus which is suitable for carrying out the plating method according to the present invention is so constructed like a known apparatus that a film supplied progressively from a supply reel (not shown) on which the film is wound may be subjected to acid and water cleansing, plated continuously in an electroplating tank and wound progressively on a take-up reel (not shown).

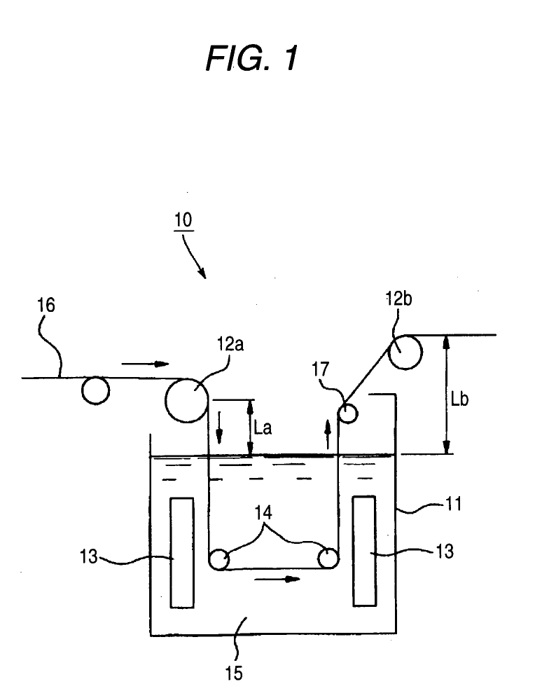

FIG. 1 shows by way of example an electroplating tank which is suitable for carrying out the plating method according to the present invention. The electroplating tank 10 shown in FIG. 1 is adapted for plating an elongate film 16 continuously. Arrows show the direction in which the film 16 is conveyed.

The electroplating tank 10 has a plating bath 11 storing a plating solution 15. A pair of parallel anode plates 13 are installed in the plating bath 11 and a pair of guide rollers 14 are installed inwardly of the anode plates 13. The guide rollers 14 are vertically movable to control the plating time for the film 16.

Current feed rollers (cathodes) 12a and 12b are mounted above the plating bath 11 for feeding an electric current to the film 16, while moving it into and out of the plating bath 11. A pair of drain rollers 17 are mounted above the plating bath 11 and below the outlet current feed roller 12b for the film leaving the plating bath 11 and a cleansing water spray (not shown) is installed between the drain rollers 17 and the current feed roller 12b for removing the plating solution from the film.

The anode plates 13 are connected to the plus terminals of a power source apparatus (not shown) by electric cables (not shown) and the current feed rollers 12a and 12b are connected to the minus terminals of the power source apparatus (not shown), so that the amount of the electric current which is fed may be controlled by an appropriate circuit.

The cathodes are preferably in the form of current feed rollers, as stated above. While the current feed rollers may be of the full or partial feed type, they are preferably of the full feed type to avoid any non-uniformity of the current density and any non-uniform plating.

The electroplating tank 10 is preferably so constructed that, when it measures, for example, from 10 cm by 10 cm by 10 cm to 100 cm by 200 cm by 300 cm, the lowest boundary of contact between the inlet current feed roller 12a and the film 16 and the surface of the plating solution may have therebetween a distance (La in FIG. 1) of from 0.5 to 15 cm, more preferably from 1 to 10 cm and still more preferably from 1 to 7 cm.

The lowest boundary of contact between the outlet current feed roller 12b and the film 16 and the surface of the plating solution preferably have a distance (Lb in FIG. 1) of 0.5 to 15 cm therebetween.

Description will now be made of a method of plating a film by employing a plating apparatus including the electroplating tank 10 described above. The method is started by putting the plating solution 15 in the plating bath 11.

An acidic copper plating bath, such as of copper sulfate, pyrophosphate, cyanide or borofluoride, is preferably used as the plating bath and a copper sulfate bath is, among others, preferred for reasons including a low cost of preparation and easy control.

Any copper compound dissolved in an ordinary acidic solution can be employed without any particular limitation as a copper ion source in an acidic copper plating bath. Specific examples of copper compounds are copper sulfate, copper oxide, copper chloride, copper carbonate, copper pyrophosphate, copper alkanesulfonates such as copper methanesulfonate or propanesulfonate, copper alkanolsulfonates such as copper propanolsulfonate, organic copper compounds such as copper acetate, citrate or tartrate, and their salts. It is preferable from the standpoints of cost, waste disposal, etc. to use copper sulfate or oxide and more preferably copper sulfate pentahydrate.

A single copper compound or a combination of two or more may be employed.

The plating solution in an acidic copper plating bath preferably has a copper content of 150 to 300 g/l as expressed by the weight of copper sulfate pentahydrate.

It is usual to employ for electroplating a plating solution having a copper content of 80 to 100 g/l. However, when a film having a high surface resistance is electroplated as in the case of the present invention, the failure of electrons to cover a wide area brings about a high current density per unit area and as no ordinary copper ion concentration makes a sufficient supply of copper ions for the electrons, the generation of hydrogen on a film surface results in copper plating of low quality (called “burning”) and makes it difficult to form a uniform plating film. The present invention employs a plating solution having a copper content of 150 g/l or more to prevent any such “burning” and form a uniform plating film.

Its copper content has an upper limit of 300 g/l, since a higher content than 300 g/l is hardly expected to produce any better result, but is uneconomical, and also presents problems including a prolonged dissolving time.

Its copper content is preferably from 150 to 250 g/l and more preferably from 180 to 220 g/l.

The plating solution preferably has a sulfuric acid content of from 30 to 300 g/l and more preferably from 50 to 150 g/l.

The plating solution preferably contains a chlorine ion in addition to the above materials and its content is preferably from 20 to 150 mg/l and more preferably from 30 to 100 mg/l.

The plating solution preferably contains a sulfur compound, too. The sulfur compound enables the plating solution to form a copper plating layer improved in density, scratch resistance, heat resistance, etc.

It is possible to employ a sulfur compound selected from sulfoalkylsulfonic acids and their salts, a group consisting of bis-sulfo organic compounds and dithiocarbamic acid derivatives, thiosulfuric acid and its salts. A single sulfur compound or a combination of two or more may be employed. The sulfur compound is preferably employed in the concentration of from 0.02 to 2,000 mg/l and more preferably from 0.1 to 300 mg/l.

The plating solution preferably contains a nitrogen compound, too. The nitrogen compound enables the plating solution to form a plating layer of improved thickness uniformity.

It is possible to employ a nitrogen compound selected from the group consisting of polyalkyleneimine, 1-hydroxy-ethyl-2-alkylimidazoline salt, Auramines and their derivatives, Methyl Violets and their derivatives, Crystal Violets and their derivatives, Janus Black and its derivatives and Janus Green. A single nitrogen compound or a combination of two or more may be employed. The nitrogen compound is preferably employed in the concentration of from 0.1 to 1,000 mg/l and more preferably from 0.5 to 150 mg/l.

The plating solution preferably contains a polymer, too. The polymer enables the plating solution to form a plating layer having an improved adhesion to its substrate.

It is possible to employ as the polymer a compound selected from the group consisting of polyethylene glycol, polypropylene glycol, a Pluronic surface active agent, a Tetronic surface active agent, polyethylene glycol glycerol ethers and polyethylene glycol dialkyl ethers. A single polymer or a combination of two or more may be employed. The polymer is preferably employed in the concentration of from 0.02 to 5,000 mg/l and more preferably from 0.1 to 1,000 mg/l.

There is no particular limitation as to how the plating solution 15 should be stirred, but a common method, such as aeration or ultrasonic stirring, may be employed. The plating solution and cleansing water preferably have a temperature of from 15 to 40° C. and more preferably from 20 to 30° C.

After the plating solution 15 has been put in the plating bath 11, the film 16 is set in position on the supply reel (not shown) and is so wound on a conveyor roller (not shown) that its side to be plated in the film 16 may contact the current feed rollers 12a and 12b.

A voltage is applied to the anode plates 13 and the current feed rollers 12a and 12b and the film 16 is conveyed in contact with the current feed rollers 12a and 12b. The film 16 is introduced into the plating bath 11 and dipped in the plating solution 15, whereby a copper plating layer is formed thereon. The plating solution 15 is wiped off the film 16 passing between the drain rollers 17 and is collected in the plating bath 11. These operations are repeated by a plurality of electroplating tanks and finished by water cleansing and winding on the take-up reel (not shown).

The film 16 is preferably conveyed at a speed of 1 to 30 m/min. Its conveying-speed is more preferably from 1 to 10 m/min. and still more preferably from 2 to 5 m/min.

The number of the electroplating tanks is not specifically limited, but is preferably from 2 to 25 and more preferably from 15 to 20.

The voltage which is applied is preferably from 1 to 100 V and more preferably from 1 to 60 V. When there are a plurality of electroplating tanks, the voltage applied thereto is preferably lowered gradually. The current applied at the inlet of the first tank is preferably from 1 to 30 A and more preferably from 2 to 10 A.

The current feed rollers 12a and 12b are preferably in contact with the whole surface of the film (their substantially electrical contact occupies 80% or more of the area of their contact).

Shower or like devices are preferably installed near the current feed rollers 12a and 12b and the film between the current feed rollers 12a and 12b and the surface of the plating solution 15 for cooling the current feed rollers 12a and 12b and the film 16.

The plating in the electroplating tank is preferably preceded by water and acid cleansing. A solution containing sulfuric acid, etc. can be employed for acid cleansing.

The plating as described above gives a film surface plated with an electrically conductive metal film formed from, for example, copper. When the plated film is used as an electromagnetic wave shielding film for a display, the electrically conductive metal film is preferably formed with a small thickness to enable the display to have a wide angle of vision. The film is also required to have a small thickness to meet a demand for high density when it is used as an electrically conductive wiring material. Under these circumstances, the electrically conductive metal film formed by plating preferably has a thickness of less than 9 μm, more preferably from 0.1 μm inclusive to less than 5 μm and still more preferably from 0.1 μm inclusive to less than 3 μm.

The plating method according to the present invention can form a uniform plating layer by employing a plating solution having a copper content of 150 to 300 g/l and can form a plating layer of satisfactory thickness by electroplating and thereby accomplish an efficient plating job without relying on electroless plating, as described above.

The plating method of the present invention is applicable to any film. It is applicable to even a film having a high surface resistance in the range of from 1 to 1,000 ohms per square, preferably from 5 to 500 ohms per square and more preferably from 10 to 100 ohms per square.

The film is desirably a film patterned with a silver mesh and its silver-mesh pattern is preferably continuous (not electrically discontinuous). Even a partially connected pattern is acceptable, since the discontinuity of an electrically conductive pattern is likely to result in the formation of a portion not plated in the first electroplating tank, or a layer lacking uniformity. The plating of a silver mesh pattern forms an electrically conductive metal film on the silver mesh and the plated film (conductive) is useful as, for example, a printed wiring board formed on an insulator film or an electromagnetic wave shielding film for PDP.

The silver mesh may be formed by any method, but is desirably formed from developed silver. A film having a silver-mesh pattern formed from developed silver is preferably formed by exposing to light a photosensitive material having an emulsion layer containing a silver salt emulsion on a support and developing it. Description will now be made of the composition of such a photosensitive material and a method of manufacturing a film having a silver-mesh pattern formed from developed silver by using such a photosensitive material.

1. Photosensitive Material

[Emulsion Layer]

The photosensitive material preferably has an emulsion layer containing a silver salt emulsion as a light sensor on a support. A known coating technique can be employed for forming an emulsion layer on a support. The emulsion layer may contain a dye, a binder, a solvent, etc. as required in addition to the silver salt emulsion. The following is a description of the components of the emulsion layer:

(Dye)

The emulsion layer may contain a dye. The dye is employed as a filter dye or for various purposes including the prevention of irradiation. The dye may be a solid disperse dye. Preferred dyes are those represented by general formulas (FA), (FA1), (FA2) and (FA3) in Official Gazette JP-A-Hei-9-179243, and more specifically, compounds F1 to F34 shown therein. Other preferred examples are (II-2) to (II-24), (III-5) to (III-18) and (IV-2) to (IV-7) shown in Official Gazette JP-A-Hei-7-152112.

Other usable dyes include the cyanine, pyrylium and aminium dyes described in Official Gazette JP-A-Hei-3-138640 as fine solid particle disperse dyes discolored at the time of development or fixing. Dyes not discolored at the time of such treatment include fine solid particle dispersions of a cyanine dye having a carboxyl group as described in Official Gazette JP-A-Hei-9-96891, a cyanine dye not containing any acidic group as described in Official Gazette JP-A-Hei-8-245902, a lake type cyanine dye as described in Official Gazette JP-A-Hei-8-333519, a cyanine dye as described in Official Gazette JP-A-Hei-1-266536, a holopolar cyanine dye as described in Official Gazette JP-A-Hei-3-136038, a pyrylium dye as described in Official Gazette JP-A-Sho-62-299959, a polymer type cyanine dye as described in Official Gazette JP-A-Hei-7-253639 and an oxonol dye as described in Official Gazette JP-A-Hei-2-282244, light-scattering particles as described in Official Gazette JP-A-Sho-63-131135, Yb3+ compound as described in Official Gazette JP-A-Hei-9-5913 and an ITO powder as described in Official Gazette JP-A-Hei-7-113072. It is also possible to employ the dyes represented by general formulas (F1) and (F2) in Official Gazette JP-A-Hei-9-179243, more specifically the compounds F35 to F112 shown therein.

The dye may contain a water-soluble dye. Examples of the water-soluble dyes are oxonol, benzylidene, merocyanine, cyanine and azo dyes. Oxonol, hemioxonol and benzylidene dyes are, among others, useful. Specific examples of the water-soluble dyes are described in British Patents Nos. 584,609 and 1,177,429, Official Gazettes JP-A-Sho-48-85130, JP-A-Sho-49-99620, JP-A-Sho-49-114420, JP-A-Sho-52-20822, JP-A-Sho-59-154439 and JP-A-Sho-59-208548, and U.S. Pat. Nos. 2,274,782, 2,533,472, 2,956,879, 3,148,187, 3,177,078, 3,247,127, 3,540,887, 3,575,704, 3,653,905 and 3,718,427.

The amount of the dye in the emulsion layer which is preferable in view of the advantages including the prevention of irradiation and a lowering of sensitivity by an increase of the amount is from 0.01 to 10% and more preferably from 0.1 to 5% by mass relative to its total solid content. (In this specification, mass ratio is equal to weight ratio.)

(Silver Salt Emulsion)

While an inorganic silver salt, such as silver halide and an organic silver salt, such as silver acetate, are available for a silver salt emulsion, it is preferable to employ a silver halide emulsion having an outstanding property as a light sensor. Techniques relating to silver halide and employed for silver salt photographic films, printing paper, films for printing plate making, emulsion masks for photo-masking, etc. can be employed for the photosensitive material according to the present mode of carrying out the invention.

The halogen in the silver halide may be any of chlorine, bromine, iodine and fluorine, or a combination thereof. For example, a silver halide composed mainly of AgCl, AgBr and AgI, is preferable, and a silver halide composed mainly of AgBr and AgCl is more preferable.

Silver chlorobromide, silver iodo-chlorobromide and silver iodobromide are preferably employed, too. Silver chlorobromide, silver bromide, silver iodo-chlorobromide or silver iodobromide is more preferable, and silver chlorobromide or iodochlorobromide containing 50 mole % or more of silver chloride is still more preferable.

The expression “silver halide composed mainly of AgBr (silver bromide)” as herein used means a silver halide containing a bromide ion occupying a molar proportion of 50% or more in the silver halide composition. Silver halide particles composed mainly of AgBr may further contain an iodide or chloride ion in addition to the bromide ion.

Silver halide is a solid particulate and preferably has an average particle size of from 0.1 to 1,000 nm (1 μm), more preferably from 0.1 to 100 nm and still more preferably from 1 to 50 nm as expressed by its equivalent spherical diameter to have a properly shaped silver-mesh pattern formed by exposure and development.

The equivalent spherical diameter of silver halide particles means the diameter of spherical particles which are equivalent thereto in volume.

The shape of silver halide particles is not specifically limited, but may be any of various shapes, such as spherical, cubic, planar (hexagonal, triangular, square, etc.), octahedral and a polyhedron having 14 faces, though it is preferably a cube or a polyhedron having 14 faces.

The silver halide particles may have their inner and surface layers formed from uniform or different phases. They may have local layers of different halogens in their interior or surface.

The silver halide emulsion used as a coating solution for an emulsion layer can be prepared by employing a method as described in, for example, P. Glafkides: Chimie et Physique Photographique (Paul Montel, 1967), G. F. Dufin: Photographic Emulsion Chemistry (The Forcal Press, 1966) or V. L. Zelikman et al.: Making and Coating Photographic Emulsion (The Forcal Press, 1964).

Therefore, either an acidic or a neutral method can be employed for preparing the silver halide emulsion, and a unilateral mixing method, a simultaneous mixing method or a combination thereof can be employed for reacting a soluble silver salt and a soluble halogen salt with each other.

Silver particles may be formed by employing a method in which they are formed in an excess of silver ions (so-called inverse mixing). Moreover, a method in which the pAg of the liquid phase in which silver halide is formed is kept at a fixed level, or the so-called controlled double-jet process may be employed as one form of simultaneous mixing method.

It is also preferable to form particles by using a silver halide solvent, such as ammonia, thioether or tetrasubstituted thiourea. It is more preferable to use a tetrasubstituted thiourea compound as described in Official Gazette JP-A-Sho-53-82408 or JP-A-Sho-55-77737.

Preferred thiourea compounds are tetramethylthiourea and 1,3-dimethyl-2-imidazolidinethion. The amount in which the silver halide solvent is used depends on the compound which is used, the intended particle size and the halogen which it contains, but is preferably from 10⁻⁵ to 10⁻² mole per mole of silver halide.

The controlled double-jet process and the method of forming particles by using a silver halide solvent facilitate the preparation of a silver halide emulsion having a regular crystal form and a narrow particle size distribution and are preferably employed therefor.

In order to realize a uniform particle size, it is preferable to make silver grow rapidly to the extent not exceeding a critical degree of saturation, by varying the rate of addition of silver nitrate or alkali halide in accordance with the rate of particle growth as described in British Patent No. 1,535,016 and Official Gazettes JP-B-Sho-48-36890 and JP-B-Sho-52-16364, or by altering the concentration of an aqueous solution as described in British Patent No. 4,242,445 and Official Gazette JP-A-Sho-55-158124.

The silver halide emulsion used to form an emulsion layer is preferably a monodisperse emulsion having a variation coefficient of 20% or less, more preferably 15% or less and still more preferably 10% or less, as expressed by {(Standard deviation of particle size)/(Average particle size)}×100.

The silver halide emulsion may be a mixture of a plurality of kinds of silver halide emulsions differing in particle size from one another.

The silver halide emulsion may contain a metal of group VIII or VIIB. It preferably contains e.g. a rhodium, iridium, ruthenium, iron or osmium compound to realize a high contrast and a low degree of fogging. These compounds may be of the type having various kinds of ligands and examples of the ligands are a cyanide ion, a halogen ion, a thiocyanato ion, a nitrosyl ion, water, a hydroxide ion, other pseudo-halogens, ammonia, amines (such as methylamine and ethylenediamine), heterocylic compounds (such as imidazole, thiazole, 5-methylthiazole and mercaptoimidazole), and organic molecules, such as urea and thiourea.

In order to realize a high degree of sensitivity, it is beneficial to employ a dope of a hexacyano-metal complex, such as K₄[Fe(CN)₆], K₄[Ru(CN)₆] or K₃[Cr(CN)₆]

The rhodium compound may be a water-soluble rhodium compound. Examples of the water-soluble rhodium compounds are a halogenated rhodium (III) compound, a hexachlororhodium (III) complex salt, a pentachloroaquorhodium complex salt, a tetrachlorodiaquorhodium complex salt, a hexabromorhodium (III) complex salt, a hexamminerhodium (III) complex salt and K₃Rh₂Br₉.

These rhodium compounds are dissolved in water or any other appropriate solvent when they are used, and it is possible to add an aqueous solution of hydrogen halide (e.g. hydrochloric, hydrobromic or hydrofluoric acid) or an alkali halide (e.g. KCl, NaCl, KBr or NaBr) as is usual to stabilize a solution of the rhodium compound. It is alternatively possible to add separate silver halide particles doped with rhodium and have it dissolved when preparing a silver halide emulsion, instead of using a water-soluble rhodium compound.

Examples of the iridium compounds are a hexachloro-iridium complex salt such as K₂IrCl₆ or K₃IrCl₆, a hexabromo-iridium complex salt, a hexammineiridium complex salt and a pentachloronitrosyliridium complex salt.

Examples of the ruthenium compounds are hexachloro-ruthenium, pentachloronitrosylruthenium and K₄[Ru(CN)₆].

Examples of the iron compounds are potassium hexacyanoferrate (II) and ferrous thiocyanate.

Ruthenium and osmium are added in the form of water-soluble complex salts as described in e.g. Official Gazettes JP-A-Sho-63-2042, JP-A-Hei-1-285941, JP-A-Hei-2-20852 and JP-A-Hei-2-20855, and a hexyligand complex as represented by the following formula is, among others, preferred:
[ML₆]⁻ⁿ
(where M stands for Ru or Os, and n stands for 0, 1, 2, 3 or 4.)

The counter ion is of no importance, but may, for example, be an ammonium or alkali metal ion. Examples of the preferred ligands are halide, cyanide, cyanate, nitrosyl and thionitrosyl ligands. Specific examples of the complexes which can be employed in accordance with the present invention, though they are not intended for limiting the present invention:

[RuCl₆]⁻³, [RuCl₄(H₂O)₂]⁻¹, [RuCl₅(NO)]⁻², [RuBr₅(NS)]⁻², [Ru (CO)₃Cl₃]⁻², [Ru(CO)Cl₅]⁻², [Ru(CO)Br₅], [OsCl₆]⁻³, [OsCl₅(NO)]⁻² [Os(NO)(CN)₅]⁻², [Os(NS)Br₅]², [Os (CN)₆]⁻⁴, [Os(O)₂(CN)₅]⁻⁴.

These compounds are preferably added in the amount of from 10⁻¹⁰ to 10⁻² mole and more preferably from 10⁻⁹ to 10⁻³ mole per mole of Ag in silver halide.

It is also preferable to use silver halide containing a Pd(II) ion or metallic palladium. Palladium may be uniformly distributed in silver halide particles, but are preferably present near the surface layers thereof. The expression “present near the surface layers thereof” means that silver halide particles have a higher palladium content in their layers having a depth within 50 nm below their surfaces than in any other layers.

These silver halide particles can be prepared by adding palladium during the formation of silver halide particles and preferably by adding palladium after the addition of a total of at least 50% of silver and halide ions. It is also preferable to add a Pd (II) ion during post-aging so that palladium may be present in the surface layers of silver halide particles.

The amount of the Pd ion and/or metallic Pd which silver halide contains is preferably from 10⁻⁴ to 0.5 mole and more preferably from 0.01 to 0.3 mole per mole of silver in silver halide.

Examples of the palladium compounds which can be used are PdCl₄ and Na₂PdCl₄.

In order to realize an improved sensitivity as a light sensor, it is possible to rely on chemical sensitization which is employed for a photographic emulsion. Methods of chemical sensitization include chalcogen sensitization such as sulfur, selenium or tellurium sensitization, noble metal sensitization such as gold sensitization, and reduction sensitization. A single method or a combination of methods can be employed. As regards a combination of methods of chemical sensitization, it is preferable to employ a combination of, for example, the sulfur and gold methods, the sulfur, selenium and gold methods, or the sulfur, tellurium and gold methods of sensitization.

Sulfur sensitization is usually carried out by adding a sulfur sensitizer to the emulsion and stirring it at a high temperature of 40° C. or above for a certain length of time. The sulfur sensitizer may be a known compound, for example, a sulfur compound contained in gelatin, or any of various other sulfur compounds such as thiosulfates, thioureas, thiazoles and rhodanines. Preferred sulfur compounds are thiosulfates and thiourea compounds. The amount of the sulfur sensitizer to be employed depends on various factors including the pH and temperature for chemical aging and the size of silver halide particles, but is preferably from 10⁻⁷ to 10⁻² mole and more preferably from 10⁻⁵ to 10⁻³ mole per mole of silver halide.

A known selenium compound can be used as the selenium sensitizer for selenium sensitization. Selenium sensitization is usually performed by adding an unstable and/or a nonunstable selenium compound to the emulsion and stirring it at a high temperature of 40° C. or above for a certain length of time. As the unstable selenium compound, it is possible to use any of the compounds as described in e.g. Official Gazettes JP-B-Sho-44-15748, JP-B-Sho-43-13489, JP-A-Hei-4-109240 and JP-A-Hei-4-324855. It is preferable to use, among others, the compounds represented by general formulas (VIII) and (IX) in JP-A-Hei-4-324855.

The tellurium sensitizer for tellurium sensitization is a compound which forms silver telluride presumed to form a sensitizing nucleus in the surface or interior of silver halide particles. The rate of formation of silver telluride in a silver halide emulsion can be tested by the method described in Official Gazette JP-A-Hei-5-313284. More specifically, it is possible to use the compounds as described in U.S. Pat. Nos. 1,623,499, 3,320,069 and 3,772,031, British Patents Nos. 235,211, 1,121,496, 1,295,462 and 1,396,696, Canadian Patent No. 800,958, Official Gazettes JP-A-Hei-4-204640, JP-A-Hei-4-271341, JP-A-Hei-4-333043 and JP-A-Hei-5-303157, Journal of Chemical Society Chemical Communication (J. Chem. Soc. Chem. Commun.), 635 (1980), ibid 1102 (1979), ibid 645 (1979), Journal of Chemical Society Perkin Transaction (J. Chem. Soc. Perkin Trans.), 1, 2191 (1980), S. Patai: The Chemistry of Organic Selenium and Tellurium Compounds, Vol. 1 (1986) and Vol. 2 (1987). The compounds represented by general formulas (II), (III) and (IV) in JP-A-Hei-5-313284 are, among others, preferred.

The amount of the selenium or tellurium sensitizer to be employed depends on the silver halide particles employed, the conditions of chemical aging, etc., but is usually from 10⁻⁸ to 10⁻² mole and preferably from 10⁻⁷ to 10⁻³ mole per mole of silver halide. The present invention does not specifically limit the conditions of chemical sensitization, but prefers a pH of 5 to 8, a pAg of 6 to 11 and more preferably 7 to 10 and a temperature of 40 to 95° C. and more preferably 45 to 85° C.

Examples of the noble metal sensitizers are gold, platinum, palladium and iridium and gold sensitization is, among others, preferred. Specific examples of the gold sensitizers used for gold sensitization are chloroauric acid, potassium chloroaurate, potassium aurithiocyanate, gold sulfide, gold (I) thioglucose and gold (I) thiomannose and they can be employed in the amount of, say, 10⁻⁷ to 10⁻² mole per mole of silver halide. The silver halide emulsion used in accordance with the present invention may contain a cadmium salt, a sulfite, a lead salt, a thallium salt, etc. during the process of formation or physical aging of silver halide particles.

Reduction sensitization may be employed for a silver salt emulsion. A stannous salt, amines, formamidinesulfinic acid, a silane compound, etc. can be employed as a reduction sensitizer. A thiosulfonic acid compound may be added to the silver halide emulsion in the manner described in European Patent Publication (EP) 293,917. A single silver halide emulsion or a combination of two or more emulsions (differing in, for example, their average particle size, the halogen which they contain, their crystal habit, conditions for chemical sensitization, or their sensitivity) may be employed for preparing a photosensitive material according to the present invention. In order to realize a high contrast, it is preferable to employ an emulsion of higher sensitivity for coating a layer closer to a support, as stated in Official Gazette JP-A-Hei-6-324426.

(Binder)

A binder can be employed in the emulsion layer for dispersing silver salt particles uniformly and aiding its adhesion to the support. A water-insoluble and a water-soluble polymer can both be employed as the binder, though a water-soluble polymer is preferred.

Examples of the binder are gelatin, polyvinyl alcohol (PVA), polyvinyl pyrrolidone (PVP), starch and other poly-saccharides, celluloses and their derivatives, polyethylene oxide, polysaccharides, polyvinylamine, chitosan, poly-lysine, polyacrylic acid, polyalginic acid, polyhyaluronic acid and carboxycellulose. They are neutral, anionic or cationic, depending on the ionic property of the functional group.

The amount of the binder which the emulsion layer may contain is not specifically limited, but may be selected as required to be effective for desired dispersion and adhesion.

(Solvent)

The solvent to be used for forming the emulsion layer is not specifically limited, but may, for example, be any of water, organic solvents (for example, alcohols such as methanol, ketones such as acetone, amides such as formamide, sulfoxides such as dimethylsulfoxide, esters such as ethyl acetate, and ethers), ionic liquids and their mixtures.

The amount of the solvent in the emulsion layer is preferably in the range of from 30 to 90% and more preferably from 50 to 80% by mass relative to the total mass of the silver salt, binder, etc. in the emulsion layer.

[Support]

The support for a photosensitive material may, for example, be a plastic film or sheet, or a glass sheet.

The plastic film or sheet may be of any of, for example, polyesters such as polyethylene terephthalate (PET) and polyethylene naphthalate, polyolefins such as polyethylene (PE), polypropylene (PP), polystyrene and EVA, vinyl resins such as polyvinyl chloride and polyvinylidene chloride, polyether ether ketone (PEEK), polysulfone (PSF), pqlyether sulfone (PES), polycarbonates (PC), pqlyamides, polyimides, acrylic resins and triacetyl cellulose (TAC).

According to the present invention, the plastic film is preferably a polyethylene terephthalate film because of its transparency, heat resistance, ease of handling and cost.

When a plated electrically conductive film is used as an electromagnetic wave shielding film for a display, its support is desired to have a high level of transparency, since the electromagnetic wave shielding film is required to be transparent. Therefore, it is preferable to employ a plastic film or sheet having a total visible light transmittance of from 70 to 100%, more preferably from 85 to 100% and still more preferably from 90 to 100%. It is possible to employ a plastic film or sheet colored to the extent not affecting the application for which the electrically conductive film will be used.

The plastic film or sheet may be of a single layer, or a multilayer film or sheet composed of two or more layers.

The plastic film or sheet preferably has a thickness of 200 μm or less, more preferably from 20 to 180 μm and still more preferably from 50 to 120 μm.

When a glass sheet is used as a support, its kind is not specifically limited, but it is preferable to employ a reinforced glass sheet having a reinforcing layer formed on its surface when the electrically conductive film is used as an electromagnetic wave shielding film for a display. Reinforced glass is more resistant to breakage than glass not reinforced. Moreover, reinforced glass made by an air cooling method is preferable from a safety standpoint, since when it is broken, it forms only small fragments and does not form any sharp edge.

[Protective Layer]

The photosensitive material may have a protective layer formed from a binder, such as gelatin or a high polymer, on its emulsion layer. The protective layer improves its scratch resistance and mechanical properties. However, it is preferable from a plating standpoint not to form any protective layer, and in the event that a protective layer is formed, it is preferably of a small thickness (for example, 0.2 μm or less). Any known coating method can be employed without any particular limitation for forming a protective layer.

2. Manufacture of a Film Having a Silver-Mesh Pattern

The photosensitive material as described above is exposed and subjected to development and any other treatment, as required, to make a film having a silver-mesh pattern. Each stage of the process will now be described.

[Exposure]

Exposure may be carried out by employing an electromagnetic wave. Examples of the electromagnetic waves which can be employed are light such as visible or ultraviolet, and radioactive rays such as X-rays. It is also possible to employ for exposure a light source having a wavelength distribution, or a light source having a specific wavelength.

Referring to the light source, it is possible to mention scanning exposure using a cathode ray tube (CRT). An exposing device including a cathode ray tube is simple, compact and inexpensive as compared with a laser device. It also facilitates the control of light axis and color. The cathode ray tube used for image exposure employs any of various light-emitting materials emitting light in different spectral regions, as required. It employs, for example, a red, a green or a blue light-emitting material, or a mixture thereof. The spectral regions are not limited to red, green and blue, but may further include yellow, orange, violet and infrared regions. It is often the case to employ a cathode ray tube having a mixture of light-emitting materials which emits white light. An ultraviolet lamp is also preferable and the g- and i-rays of a mercury lamp are also employed.

Various laser beams can also be employed for exposure. For example, it is preferable to use a scanning exposure system employing monochromatic high-density light, such as a gas laser, a light-emitting diode, a semiconductor laser or a second harmonic generating (SHG) light source obtained by combining a semiconductor laser or a solid laser having a semiconductor laser as an exciting light source and a nonlinear optical crystal, and it is also possible to employ a KrF or ArF excimer laser or an F2 laser. A semiconductor laser or a second harmonic generating (SHG) light source obtained by combining a semiconductor or solid laser and a nonlinear optical crystal is preferably employed for a compact and inexpensive system for exposure. It is particularly preferable to employ a semiconductor laser for exposure in order to design a compact and inexpensive apparatus having a long life and ensuring a high level of safety.

Specific examples of preferred lasers are a blue semiconductor laser having a wavelength of 430 to 460 nm (announced by NICHIA KAGAKU at the 48th United Lecture Meeting of the Japan Society of Applied Physics in March, 2001), a green laser having a wavelength of about 530 nm as obtained by converting the wavelength of a semiconductor laser (having an oscillating wavelength of about 1,060 nm) by a SHG crystal of LiNbO₃ having a waveguide type inverted domain structure, a red semiconductor laser having a wavelength of about 685 nm (HITACHI Model No. HL6738MG) and a red semiconductor laser having a wavelength of about 650 nm (HITACHI Model No. HL6501MG).

Exposure is preferably performed in a grid or like pattern. Exposure in such a pattern may be accomplished by plane exposure using a photomask, or by scanning exposure using a laser beam. It is possible to employ refractive exposure using a lens, reflective exposure using a reflecting mirror or any other method of exposure, such as contact, proximity, reduced projection or reflected projection exposure.

[Development]

Development may be carried out by employing any ordinary technique for development as employed for silver salt photographic films, printing paper, films for printing plate making or emulsion masks for photomasking. As regards developers, there is no particular limitation, but it is possible to use e.g. PQ, MQ and MAA developers, including commercially available products such as CN-16, CR-56, CP45X, FD-3 and PAPITOL of FUJI FILM, C-41, E-6, RA-4, D-19 and D-72 of KODAK and the developers included in their kits. A lithographic developer can also be employed.

KODAK D85 is a lithographic developer.

A developing agent of the dihydroxybenzene series can be used as a developer. Examples of the developing agents of the dihydroxybenzene series are hydroquinone, chlorohydro-quinone, isopropylhydroquinone, methylhydroquinone and hydroquinone monosulfonate and hydroquinone is, among others, preferred. Auxiliary developing agents showing superadditivity to the developing agents of the dihydroxybenzene series are 1-phenyl-3-pyrazolidones and p-aminophenols. A combination of the developing agents of the dihydroxybenzene series with 1-phenyl-3-pyrazolidones or p-aminophenols is preferably employed as a developer for the manufacturing method of the present invention.

Specific examples of the developing agents which can be combined with 1-phenyl-3-pyrazolidone or a derivative thereof used as an auxiliary developing agent are 1-phenyl-3-pyrazolidone, 1-phenyl-4,4-dimethyl-3-pyrazolidone and 1-phenyl-4-methyl-4-hydroxymethyl-3-pyrazolidone.

Examples of the auxiliary developing agents of the p-aminophenol series are N-methyl-p-aminophenol, p-aminophenol, N-(β-hydroxyethyl)-p-aminophenol and N-(4-hydroxyphenyl)-glycine and N-methyl-p-aminophenol is, among others, preferred. The developing agent of the dihydroxybenzene series is preferably employed in the amount of from 0.05 to 0.8 mole per liter, more preferably 0.23 mole or more per liter and still more preferably from 0.23 to 0.6 mole per liter. When dihydroxybenzenes are combined with 1-phenyl-3-pyrazolidones or p-aminophenols, the former is preferably employed in the amount of from 0.23 to 0.6 mole per liter and more preferably from 0.23 to 0.5 mole per liter, and the latter in the amount of 0.06 mole or less per liter and more preferably from 0.03 to 0.003 mole per liter.

The developer (sometimes referring to both of the starting and replenishing developers together) may contain ordinary additives (for example, a preservative and a chelate agent). Examples of the preservatives are sulfites such as sodium sulfite, potassium sulfite, lithium sulfite, ammonium sulfite, sodium bisulfite, potassium meta-bisulfite and formaldehyde sodium bisulfite. The sulfite is preferably employed in the amount of 0.20 mole or more per liter and more preferably 0.3 mole or more per liter, but up to 1.2 moles per liter, since the addition of a larger amount is likely to cause the contamination of the developer with silver. A particularly preferred amount thereof is from 0.35 to 0.7 mole per liter.

The preservative for the developing agent of the dihydroxybenzene series may contain a small amount of an ascorbic acid derivative with the sulfite. The term “ascorbic acid derivative” as herein used covers ascorbic acid, erythorbic acid as its stereoisomer and alkali metal salts (sodium and potassium salts) thereof. Sodium erythorbate is preferred for its material cost. The ascorbic acid derivative is preferably employed in a molar ratio of from 0.03 to 0.12 and more preferably from 0.05 to 0.10 to the developing agent of the dihydroxybenzene series. The developer containing an ascorbic acid derivative as the preservative preferably does not contain any boron compound.

The other additives that the developer may contain are a developing controller, such as sodium or potassium bromide; an organic solvent, such as ethylene glycol, diethylene glycol, triethylene glycol or dimethylformamide; a developing acceleartor, such as diethanolamine, triethanolamine or other alkanolmine, imidazole or a derivative thereof; and a fogging or black pepper inhibitor, such as a mercapto, indazole, benzotriazole or benzimidazole compound. Specific examples of the benzimidazole compounds are 5-nitroindazole, 5-p-nitrobenzoylaminoindazole, 1-methyl-5-nitroindazole, 6-nitroindazole, 3-methyl-5-nitroindazole, 5-nitrobenz-imidazole, 2-isopropyl-5-nitrobenzimidazole, 5-nitrobenz-triazole, sodium 4-[(2-mercapto-1,3,4-thiadiazole-2-yl)-thio]-butanesulfonate, 5-amino-1,3,4-thiadiazole-2-thiol, methylbenzotriazole, 5-methylbenzotriazole and 2-mercapto-benzotriazole. The benzoimidazole compound is preferably employed in the amount of from 0.01 to 10 millimoles and more preferably from 0.1 to 2 millimoles per liter of developer.

The developer may further contain any of various organic and inorganic chelate agents. Examples of the inorganic chelate agents are sodium tetrapolyphosphate and sodium hexametaphosphate. Main examples of the organic chelate agents are organic carboxylic acids, aminopolycarboxylic acids, organic phosphonic acids, aminophosphonic acid and organic phosphonocarboxylic acids.

The chelate agent is preferably employed in the amount of from 1×10⁻⁴ to 1×10⁻¹ mole and more preferably from 1×10⁻³ to 1×10⁻² mole per liter of developer.

The developer may further contain as a silver contamination inhibitor any of the compounds described in Official Gazettes JP-A-Sho-56-24347, JP-B-Sho-56-46585, JP-B-Sho-62-2849 and JP-A-Hei-4-362942.

It may further contain any of the compounds described in JP-A-Sho-61-267759 as a dissolving assistant. Moreover, the developer may contain a toner, a surface active agent, an anti-foaming agent, a hardener, etc. as required.

While the developing temperature and time are related to each other and depend on the total processing time, the developing temperature is preferably from about 20 to about 50° C. and more preferably from 25 to 45° C. The developing time is preferably from five seconds to two minutes and more preferably from seven seconds to one and a half minutes.

The developing job may include a fixing job done for removing the silver salt from any unexposed portion and stabilizing it. The fixing job may be carried out by employing any fixing technique as employed for silver salt photographic films, printing paper, films for printing plate making or emulsion masks for photomasking.

Description will now be made of the preferred components of a fixing solution used for the fixing job. They are sodium thiosulfate and ammonium thiosulfate, and further include tartaric acid, citric acid, gluconic acid, boric acid, iminodiacetic acid, 5-sulfosalicylic acid, glucoheptanoic acid, tiron, ethylenediaminetetracetic acid, diethylene-triaminepentacetic acid, nitrilotriacetic acid and their salts. From a standpoint of environment protection which has recently become an important issue, it is preferable for the solution not to contain any boric acid. Sodium or ammonium thiosulfate may be used as a fixing agent in the fixing solution, and while ammonium thiosulfate is preferred from a standpoint of fixing speed, it may be better from a standpoint of environment protection to use sodium thiosulfate. The amount of any such known fixing agent is variable, but is usually from about 0.1 to about 2 moles per liter. It is preferably from 0.2 to 1.5 moles per liter. The fixing solution may further contain a hardener (for example, a water-soluble aluminum compound), a preservative (for example, sulfite or bisulfite), a pH buffer agent (for example, acetic acid), a pH adjusting agent (for example, ammonia or sulfuric acid), a chelate agent, a surface active agent, a wetting agent and a fixing acceleartor, as required.

The surface active agent may be selected from, for example, an anion surface active agent such as sulfoxide or sulfonate, a polyethylene-based surface active agent and an amphoteric surface active agent as described in Official Gazette JP-A-Sho-57-6740. The fixing solution may contain a known anti-foaming agent.

The wetting agent may be selected from, for example, alkanolamine and alkylene glycol. The fixing accelerator may be selected from, for example, a thiourea derivative as described in Official Gazette JP-B-Sho-45-35754, JP-B-Sho-58-122535 or JP-B-Sho-58-122536; an alcohol having a triple bond in the molecule; a thioether compound as described in U.S. Pat. No. 4,126,459; and a meso-ionic compound as described in Official Gazette JP-A-Hei-4-229860, and a compound as described in Official Gazette JP-A-Hei-2-44355 may also be employed. The pH buffer agent may be selected from organic acids such as acetic, malic, succinic, tartaric, citric, oxalic, maleic, glycolic and adipic acids and inorganic buffer agents such as boric acid, phosphates and sulfites. The pH buffer agent is preferably selected from acetic acid, tartaric acid and sulfites. The pH buffer agent is employed for preventing any such elevation in the pH of the fixing agent by the developer carried forward thereinto and is preferably employed in the amount of, say, from 0.01 to 1.0 mole per liter and more preferably from 0.02 to 0.6 mole per liter. The fixing solution preferably has a pH of from 4.0 to 6.5 and more preferably from 4.5 to 6.0. A compound as described in Official Gazette JP-A-Sho-64-4739 may be used as a pigment dissolution accelerator.

The hardener in the fixing solution may be selected from water-soluble aluminum salts and chromium salts. The compounds preferred as the hardener are water-soluble aluminum salts, such as aluminum chloride, aluminum sulfate and potassium alum. The hardener is preferably employed in the amount of from 0.01 to 0.2 mole per liter and more preferably from 0.03 to 0.08 mole per liter.

The fixing job preferably employs a fixing temperature of about 20 to about 50° C. and more preferably from 25 to 45° C. and a fixing time of from five seconds to one minute and more preferably from seven to 50 seconds. The fixing solution is preferably replenished in an amount of 600 ml/m² or less, more preferably 500 ml/m² or less and still more preferably 300 ml/m² or less relative to the amount of the photosensitive material involved.

The photosensitive material subjected to development and fixing is preferably rinsed with water or stabilized. Its water rinsing or stabilization is usually carried out by employing 20 liters or less of water per square meter of the photosensitive material and can be carried out with a replenishment of water of three liters or less (including the case of no replenishment in which standing water is used for rinsing). This enables water saving and eliminates the necessity for any piping when an automatic developing machine is installed. A multistage countercurrent system (for example, two- or three-stage) is known as an old method of reducing the replenishment of water for rinsing. When the multistage countercurrent system is applied to the manufacturing method of the present invention, the photosensitive material is rinsed with water still more efficiently, as it is treated gradually in the right direction, or progressively in contact with the liquid not contaminated by the fixing solution. When rinsing is done with a small amount of water, it is preferable to employ a cleansing tank for a squeeze or crossover roller as described in e.g. Official Gazettes JP-A-Sho-63-18350 and JP-A-Sho-62-287252. In order to reduce a burden of environmental pollution resulting from rinsing with a small amount of water, it will be effective to add various oxidizing agents or employ a filter. Moreover, a part or all of the liquid overflowing the water rinsing or stabilizing bath as a result of its replenishment with water treated for preventing the formation of mold may be utilized as the solution for the preceding fixing step, as described in Official Gazette JP-A-Sho-60-235133. It is also effective to add a water-soluble surface active agent or an anti-foaming agent in order to prevent non-uniformity of water bubbles which is likely to occur when rinsing is done with a small amount of water, and/or prevent the transfer of substances from the squeeze roller to the treated film.

In order to prevent contamination by any dye dissolved from the photosensitive material during its water rinsing or stabilizing treatment, it is effective to place in the water rinsing tank a pigment adsorbent as described in Official Gazette JP-A-Sho-63-163456. A bath containing a compound as described in Official Gazette JP-A-Sho-46-44446, JP-A-Hei-1-102553, JP-A-Hei-2-132435 or JP-A-Hei-2-201357 may be employed as a final bath for the photosensitive material for its stabilizing treatment following its water rinsing. It is possible to add an ammonium compound, a metal compound such as of Bi or Al, a fluorescent whitening agent, a chelate agent, a film pH adjusting agent, a hardener, a germicide, a fungicide, alkanolamine and a surface active agent, as required. While it is possible to use tap water as water for rinsing or stabilization, it is preferable to use deionized water, or water sterilized by e.g. a halogen, an ultraviolet sterilizing lamp or an oxidizing agent (e.g. ozone, hydrogen peroxide or chlorate). It is also possible to use water containing a compound as described in Official Gazette JP-A-Hei-4-39652 or JP-A-Hei-5-241309.

The water rinsing or stabilizing bath temperature and time are preferably from 0 to 50° C. and from five seconds to two minutes, respectively.

The exposed area as developed preferably has a metallic silver content by mass which is equal to or more than 50% and more preferably 80% of the silver contained in that area before exposure. The exposed area having a silver content equal to or more than 50% by mass of the silver in that area before exposure exhibits a high degree of electrical conductivity.

The gradation of the developed material is not specifically limited, but is preferably in excess of 4.0. The developed material having a gradation in excess of 4.0 exhibits a high degree of electrical conductivity, while maintaining a high level of transparency in its light-transmitting portion. Its gradation can be raised to 4.0 or above by, for example, doping with a rhodium or iridium ion, as stated before.

The metallic silver portion of the developed material may be subjected to physical development. Physical development means the deposition of metal particles on the nuclei of a metal or metal compound by reducing a metal ion, such as a silver ion, with a reducing agent. Physical development is employed for making an instant B & W film, an instant slide film, a printing plate, etc. and techniques employed therefor are applicable to the present mode of carrying out the invention.

Physical development may be performed simultaneously with the development as described above, or separately thereafter.

[Oxidizing Treatment]

The developed silver portion of the developed material may be subjected to oxidizing treatment. In the event, for example, that there is any slight metal deposit in the light transmitting portion other than the developed silver portion, its oxidizing treatment removes the metal and restores the transmittance of the light-transmitting portion to nearly 100%.

A known method employing any of various oxidizing agents, such as Fe (III) ion treatment, can be employed for the oxidizing treatment. The oxidizing treatment may be performed either after the exposure and development of the emulsion layer or after its physical development or plating, or both after its development and after its physical development or plating.

Moreover, the developed silver portion as obtained by exposure and development may be treated with a solution containing palladium. Palladium may be a divalent palladium ion or metallic palladium. This treatment accelerates electroless plating or physical development.

3. Light-transmitting Electromagnetic Wave Shielding Film/Optical Filter

When the plating method of the present invention is applied to a film having a silver-mesh pattern formed by the exposure and development of a photosensitive material containing a silver salt emulsion as described above, there is obtained a light-transmitting electrically conductive film having an electrically conductive metal plating formed on a silver mesh.

This light-transmitting electrically conductive film has a high degree of electromagnetic wave shielding property and translucency and can be incorporated as an electromagnetic wave shielding film in, for example, a CRT, an EL, a liquid crystal display, a plasma display panel, or other image display panel, or an imaging semiconductor integrated circuit such as CCD. The electrically conductive metal film according to the present invention is not only employed for display devices as stated above, but is also applicable to e.g. the peep window or casing of a measuring apparatus or machine or a manufacturing apparatus generating an electromagnetic wave, or the window of a building which is likely to receive radio interference from a tower or high-tension line, or the window of a motor vehicle.

The light-transmitting electrically conductive film according to the present invention has a precise pattern of fine lines formed by a mesh of developed silver and is particularly useful as a light-transmitting electromagnetic wave shielding film on the front of an image display device, such as a plasma display panel, since it can maintain or even improve the quality of its display without lowering its brightness seriously.

The light-transmitting electromagnetic wave shielding film is desired to have its electrically conductive metal portion grounded so that its electromagnetic wave shielding power may not be lowered. Accordingly, it is desirable for the light-transmitting electromagnetic wave shielding film to have a portion of electrical continuity making electrical contact with the ground connector of a display. Its portion of electrical continuity is preferably formed around the metallic silver or electrically conductive metal portion along the edge of the film.

Its portion of electrical continuity may be formed by a mesh pattern, or may not be patterned, but may be formed by, for example, a solid metal foil, though the latter is preferred to ensure its good electrical contact with the ground connector of the display.

When the light-transmitting electrically conductive film is used as a light-transmitting electromagnetic wave shielding film, it is preferable to attach an adhesive layer, a glass sheet, a protective film; a functional film, etc. to it as will be described below, and thereby form an optical filter. Description will now be made of the layers which can be formed on the light-transmitting electrically conductive film (light-transmitting electromagnetic wave shielding film).

<Adhesive Layer>

The light-transmitting electromagnetic wave shielding film may have an adhesive layer formed on its side having the electrically conductive metal portion, or on its opposite side. An adhesive layer may also be formed between the light-transmitting electromagnetic wave shielding film and another layer (a glass sheet, a protective or functional layer, etc.) attached to it. Each adhesive layer preferably has a thickness equal to, or larger than that of the metallic silver portion (or electrically conductive metal portion), in the range of, for example, 10 to 80 μm and more preferably from 20 to 50 μm.

The adhesive layer is preferably of an adhesive having a refractive index of 1.40 to 1.70. Its refractive index of 1.40 to 1.70 diminishes its difference from the refractive index of the support for the light-transmitting electromagnetic wave shielding film and thereby prevents any lowering of its visible light transmittance.

The adhesive is preferably of the type fluidizable under heat or pressure and more preferably of the type fluidizable when heated to a temperature of 200° C. or below, or subjected to a pressure of 1 kgf/cm² or more.

Such a adhesive permits the adhesive layer to be fluidized on the display or plastic sheet to which the light-transmitting electromagnetic wave shielding film is to be stuck, and thereby facilitates its sticking to a curved surface or complicated shape by lamination or pressure forming, particularly by pressure forming.

Accordingly, the adhesive preferably has a softening temperature of 200° C. or below. As the light-transmitting electromagnetic wave shielding film is usually intended for use in an environment having a temperature below 80° C., the adhesive layer more preferably has a softening temperature of 80° C. or above, and still more preferably from 80 to 120° C. from a workability standpoint. Its softening temperature is the temperature at which it has a viscosity of 10¹² poises or below, and at which it usually begins to be fluidized in a time of, say, one to 10 seconds.

The thermoplastic resins as listed below are typical examples of the adhesives which are fluidizable under heat or pressure. They are natural rubber (refractive index n=1.52), (di)enes such as polyisoprene (n=1.521), poly-1-, 2-butadiene (n=1.50), polyisobutene (n 1.505 to 1.51), polybutene (n=1.513), poly-2-heptyl-1,3-butadiene (n=1.50), poly-2-t-butyl-1,3-butadiene (n=1.506) and poly-1,3-butadiene (n=1.515), polyethers such as polyoxyethylene (n=1.456), polyoxypropylene (n=1.450), polyvinylethyl ether (n=1.454), polyvinylhexyl ether (n=1.459) and polyvinylbutyl ether (n=1.456), polyesters such as polyvinyl acetate (n=1.467) and polyvinyl propionate (n 1.467), polyurethane (n=1.5 to 1.6), ethyl cellulose (n=1.479), polyvinyl chloride (n=1.54 to 1.55), polyacrylonitrile (n=1.52), polymethacrylonitrile (n=1.52), polysulfone (n=1.633), polysulfide (n=1.6), a phenoxy resin (n=1.5 to 1.6), and poly(meth)acrylates such as polyethyl acrylate (n=1.469), polybutyl acrylate (n=1.466), poly-2-ethylhexyl acrylate (n=1.463), poly-t-butyl acrylate (n=1.464), poly-3-ethoxy-propyl acrylate (n=1.465), polyoxycarbonyltetramethylene (n=1.465), polymethyl acrylate (n=1.472 to 1.480), polyisopropyl methacrylte (n=1.473), polydodecyl methacrylate (n=1.474), polytetradecyl methacrylate (n=1.475), poly-n-propyl methcrylate (n=1.484), poly-3,3,5-trimethylcyclohexyl methacrylate (n=1.484), polyethyl methacrylate (n=1.485), poly-2-nitro-2-methyl-propyl methacrylate (n=1.487), poly-1,1-diethylpropyl methacrylate (n=1.489), polymethyl methacrylate (n=1.489). It is also possible to use a copolymer formed from two or more such acrylic polymers, or a blend of two or more such polymers, as required.

It is also possible to use copolymers formed from acrylic and other resins, such as epoxy acrylates (n=1.48 to 1.60), urethane acrylates (n=1.5 to 1.6), polyether acrylates (n=1.48 to 1.49) or polyester acrylates (n=1.48 to 1.54). Urethane, epoxy and polyether acrylates are excellent in adhesive property. Examples of the epoxy acrylates are 1,6-hexanediol diglycidyl ether, neopentyl glycol diglycidyl ether, diglycidyl adipate, diglycidyl phthalate, polyethylene glycol diglycidyl ether, trimethylolpropane triglycidyl ether, glycerol triglycidyl ether, pentaerythritol tetraglycidyl ether, sorbitol tetraglycidyl ether and other (meth)acrylic acid adducts. Polymers having hydroxyl groups in the molecules, such as epoxy acrylates, are effective for an improved adhesive property. It is possible to use two or more such copolymer resins together, if required.

The adhesive polymer preferably has a weight-average molecular weight of 500 or higher (as determined by employing a working curve prepared from standard polystyrene by gel permeation chromatography). A polymer having a molecular weight of 500 or less gives an adhesive composition which may have too low a cohesive force to make any intimate contact with an object.

The adhesive may contain a curing agent (crosslinking agent). Examples of the curing agent which can be used for the adhesive are amines such as triethylenetetramine, xylene-diamine and diaminodiphenylmethane, acid anhydrides such as phthalic anhydride, maleic anhydride, dodecylsuccinic anhydride, pyromellitic anhydride and benzophenonetetracarboxylic anhydride, diaminodiphenylsulfone, tris(dimethyl-aminomethyl)phenol, polyamide resins, dicyandiamide and ethyl methyl imidazole. A single curing agent or a mixture of two or more may be employed.

The curing agent is employed in the amount of from 0.1 to 50 parts by weight and preferably from 1 to 30 parts by weight for 100 parts by weight of adhesive polymer. Less than 0.1 part by weight is insufficient for curing and over 50 parts by weight causes excessive crosslinking, which is likely to affect the adhesive property of the adhesive adversely.

The adhesive may further contain other additives such as a diluting agent, a plasticizer, an oxidation inhibitor, a filler, a coloring agent, an ultraviolet absorber and a tackifier, if required, in addition to the curing agent.

The adhesive layer can be formed on the light-transmitting electromagnetic wave shielding film by coating a part or the whole of its electrically conductive metal portion with an adhesive layer composition containing the adhesive polymer, curing agent and other additives, drying its solvent and curing the adhesive under heat.

<Protective Film>

The light-transmitting electromagnetic wave shielding film according to the present invention may have a protective film attached thereto. The protective film may be formed on both sides of the light-transmitting electromagnetic wave shielding film, or only on one side thereof (for example, on its electrically conductive metal portion).

The light-transmitting electromagnetic wave shielding film often has a functional film attached thereto for such purposes as reinforcing its outermost surface, imparting antireflective and anti-staining properties thereto as stated below, and when such a functional film is formed on the light-transmitting electromagnetic wave shielding film, the protective film is preferably removed therefrom. Accordingly, the protective film is preferably separable.

The protective film preferably has a peeling strength of from 5 mN to 5 N per 25 mm of width and more preferably from 10 to 100 mN per 25 mm of width. Its peeling strength below its lower limit makes the film peelable so easily that its separation may occur from its handling or careless contact, while its peeling strength over its upper limit is also undesirable, since its separation requires a large force and is moreover likely to cause the separation of the mesh-like metal foil from the transparent support film (or its adhesive layer).

The protective film is preferably a resin film formed from, for example, a polyolefin resin such as a polyethylene or polypropylene resin, a polyester resin such as a polyethylene terephthalate resin, a polycarbonate resin or an acrylic resin. The surface to which the protective film will be attached is preferably subjected to corona discharge treatment or has an easily adhering layer formed thereon.

<Functional Film>

When the light-transmitting electromagnetic wave shielding film is used for a display (particularly a plasma display), a functional film having various functions as will be described below is preferably attached to it to impart those functions thereto. The functional film can be attached to the light-transmitting electromagnetic wave shielding film by e.g. an adhesive.

(Antireflective and Anti-Staining Properties)

It is preferable to impart to the light-transmitting electromagnetic wave shielding film antireflective (AR) property for restraining the reflection of outside light or antiglare (AG) property for preventing the reflection of a mirror image or both of the antireflective and antiglare (ARAG) properties.

These properties prevent the reflection of a lighting device, etc. from disabling a display screen to be clearly visible. They lower the visible light reflectivity of the film surface and thereby not only prevent its reflection, but also provide an improved contrast, etc. The light-transmitting electromagnetic wave shielding film having an antireflective and antiglare functional film attached thereto preferably has a visible light reflectivity of 2% or less, more preferably 1.3% or less and still more preferably 0.8% or less.

The functional film can be prepared by forming an antireflective and antiglare functional layer on a suitable transparent substrate.

An antireflective layer can be formed by, for example, forming a single film of a fluorine-containing transparent high molecular resin, magnesium fluoride, a silicone resin or silicon oxide with an optical thickness equal to ¼ wavelength, or forming one upon another two or more films of inorganic compounds such as metal oxides, fluorides, silicides, nitrides and sulfides, or organic compounds such as silicone, acrylic and fluorine-containing resins, differing from one another in refractive index.

An antiglare layer can be formed from a layer having a fine surface roughness in the order of, say, 0.1 to 10 μm. More specifically, such a layer can be formed by dispersing particles of an inorganic or organic compound, such as silica, an organic silicon compound, melamine or an acrylic resin, in a thermosetting or photosetting resin, such as an acrylic, silicone, melamine, urethane, alkyd or fluorine-containing resin to prepare an ink, coating the substrate with the ink and curing it. The particles preferably have an average diameter of, say, 1 to 40 μm.

An antiglare layer can also be formed by coating the substrate with a thermosetting or photosetting resin as stated above, and pressing a pattern having a desired gloss value or surface condition against it for curing it.

The light-transmitting electromagnetic wave shielding film having an antiglare layer formed thereon preferably has a haze of from 0.5 to 20% and more preferably from 1 to 10%. Too low a haze means insufficient antiglare property and too high a haze tends to bring about a transmitted image of low clarity.

(Hard Coating Property)

The functional film preferably has hard coating property to impart scratch resistance to the light-transmitting electromagnetic wave shielding film. A hard coating layer may be of for example, an acrylic, silicone, melamine, urethane, alkyd or fluorine-containing resin and may be formed from any such material by any appropriate method without any particular limitation. The hard coating layer preferably has a thickness of, say, 1 to 50 μm. It is preferable to form an antireflective and/or antiglare layer as described above on a hard coating layer to obtain a functional film having scratch resistance and antireflective and/or antiglare property.

The light-transmitting electromagnetic wave shielding film having hard coating property imparted thereto preferably has a surface hardness of at least H, more preferably at least 2H and still more preferably at least 3H by pencil hardness according to JIS K-5400.

(Antistatic Property)

Antistatic property is preferably imparted to the light-transmitting electromagnetic wave shielding film for preventing the attraction of dust by a charge of static electricity and any discharge of static electricity by contact with a human body.

A film of high electrical conductivity, for example, having a sheet resistance not exceeding, say, 10¹¹ ohm per square can be used as a functional film having antistatic property.

A film of high electrical conductivity can be prepared by forming an antistatic layer on a transparent substrate. Specific examples of the antistatic agent used for an antistatic layer are sold under the trade names PELESTAT (Product of Sanyo Kasei) and ELECTROSTRIPPER (product of KAO). An antistatic layer can also be formed by a known transparent electrically conductive film such as of ITO, or an electrically conductive film in which ultrafine particles of ITO or electrically conductive ultrafine particles, such as of ITO or tin oxide, are dispersed. Antistatic property may also be realized by e.g. incorporating electrically conductive fine particles into the hard coating, antireflective or antiglare layer.

(Anti-Staining Property)

The light-transmitting electromagnetic wave shielding film preferably has anti-staining property so that its fouling by fingerprints, etc. may be prevented, and so that any dirt may be easily removed.

A functional film having anti-staining property can be obtained by, for example, applying an anti-staining compound to a transparent substrate. An anti-staining compound may be a compound of the nature not wetted by water or oil, and examples are fluorine and silicon compounds. A specific example of fluorine compound is available under the trade name OPTOOL (product of DAIKIN), and a specific example of silicon compound under the trade name TAKATAQUANTUM (product of NIPPON YUSI).

(Ultraviolet Blocking Property)

Ultraviolet blocking property is preferably imparted to the light-transmitting electromagnetic wave shielding film for preventing e.g. the deterioration of the pigment and transparent substrate as will be stated below. A functional film having ultraviolet blocking property can be prepared by incorporating an ultraviolet absorber into a transparent substrate or forming an ultraviolet absorbing layer thereon.

Its ultraviolet blocking power required for protecting the pigment is represented by a transmittance of 20% or less, preferably 10% or less and more preferably 5% or less for ultraviolet radiation having a wavelength shorter than 380 nm. The functional film having ultraviolet blocking property is obtained by forming on a transparent substrate a layer containing an ultraviolet absorber or an inorganic compound reflecting or absorbing ultraviolet radiation. The ultraviolet absorber can be selected from known ones of e.g. the benzotriazole or benzophenone series and its kind and concentration are not specifically limited, since they depend on its dispersibility or solubility in a medium in which it is to be dispersed or dissolved, its absorption wavelength and coefficient, the thickness of the medium, etc.

The functional film having ultraviolet blocking property preferably has a low absorption of visible light and does not have an extremely low transmittance of visible light, nor does it present any color such as yellow.

When the functional film has a layer containing any pigment as will be stated below, an ultraviolet blocking layer is preferably formed outside that layer.

(Gas Barrier Property)

If the light-transmitting electromagnetic wave shielding film is used in an environment having a temperature and a humidity which are higher than normal levels, it is likely that water may deteriorate the pigment as will be stated below, or that water may collect in the adhesive or between the layers joined together or cause the phase separation and deposition of the adhesive and cloud the film. Therefore, the light-transmitting electromagnetic wave shielding film preferably has gas barrier property.

In order to prevent any such pigment deterioration or clouding, it is necessary to prevent any water from entering the layer containing the pigment or the adhesive layer and it is preferable for the functional film to have a water vapor permeability not exceeding 10 g/m²/day and more preferably not exceeding 5 g/m²/day.

(Other Optical Characteristic)

When the light-transmitting electromagnetic wave shielding film is employed for a plasma display, infrared (particularly near-infrared) blocking property is preferably imparted to it, since the plasma display generates intense near-infrared radiation.

A functional film having near-infrared blocking property preferably has a transmittance of 25% or less, more preferably 15% or less and still more preferably 10% or less in a wavelength range of 800 to 1,000 nm.

The light-transmitting electromagnetic wave shielding film used for a plasma display preferably transmits a neutral or blue gray color. This is to maintain or improve the luminescent property and contrast of the plasma display and in view of the case in which a white color having a somewhat higher color temperature than a standard white color is preferred.

Moreover, it is understood that a color plasma display is unsatisfactory in color reproducibility, and a red display has, among others, the drawback that its luminescent spectrum shows several luminescent peaks in a wavelength range of, say, 580 to 700 nm, and that a relatively intense luminescent peak on the lower side of the wavelength range makes red luminescence close to orange and low in color purity. Therefore, it is preferable for the functional film to be capable of reducing selectively any unnecessary luminescence emitted by a fluorescent material or a discharge gas and causing the above problem.

These optical characteristics can be controlled by employing a pigment. Desired optical characteristics can be obtained by using a near-infrared absorber for blocking near-infrared radiation and employing a pigment absorbing unnecessary luminescence selectively for reducing it, and an optical filter may have a good color tone realized by employing a pigment having an appropriate absorption in the visible region.

It is possible to select the pigment from dyes or pigments having a desired absorption wavelength in the visible region or compounds known as a near-infrared absorber, for example, commercially available organic pigments such as anthraquinone, phthalocyanine, methine, azomethine, oxazine, immonium, azo, styryl, coumarine, porphyrin, dibenzofuranone, diketopyrrolopyrrole, rhodamine, xanthene, pyrromethene, dithiol and diiminium compounds.

It is preferable to employ a pigment having such heat resistance as not to be deteriorated at a temperature of, say, 80° C., since the plasma display has a high panel surface temperature and the light-transmitting electromagnetic wave shielding film also has an elevated temperature in an environment having a high temperature.

As some pigments are low in light resistance and if it is possible that the pigment may be deteriorated by the emission of the plasma display or outside ultraviolet or visible light, it is preferable to employ a functional film containing an ultraviolet absorber or having an ultraviolet blocking layer formed thereon, as stated above, in order to prevent the deterioration of the pigment by ultraviolet or visible light.

In addition to heat and light, the influence of humidity and a combination of those factors has also to be avoided. The deterioration of the pigment is likely to alter the transmission properties of the optical filter and change its color tone or lower its near-infrared blocking power.

It is also preferable for the pigment to be easily soluble or dispersible in a solvent for its dissolution or dispersion in a resin composition for the transparent substrate or a coating composition for the coating layer.

The concentration of the pigment depends on its absorption wavelength and coefficient, the transmission properties or transmittance as required of the light-transmitting electromagnetic wave shielding film and the kind and thickness of the medium or coating in which it is dispersed.

In order to form a functional film containing a pigment, its transparent substrate may contain the pigment or have its surface coated with a layer containing the pigment. It is also possible for the adhesive layer to contain the pigment. It is possible to form a single layer containing a mixture of two or more pigments having different absorption wavelengths, or two or more layers containing the pigments separately.

As some pigments are deteriorated by their contact with a metal, the functional film containing any such pigment is preferably so formed that its pigment-containing layer may not contact the electrically conductive metal portion of the light-transmitting electromagnetic wave shielding film.

### EXAMPLES

The present invention will now be described more specifically by examples thereof. Variations or alterations may be made in the materials, amounts, proportions, treatments, procedures thereof, etc. appearing in the following description of the examples without departing from the scope and spirit of the present invention. Accordingly, the scope of the present invention should not be interpreted to be limited by the following examples.

### Example 1

### Preparation of a Silver Halide Photosensitive Material

An emulsion containing silver iodobromochloride particles having an average equivalent spherical diameter of 0.1 μm (I=0.2 mole %, Br=40 mole %) was prepared and contained 10.0 g of gelatin against 60 g of Ag in an aqueous medium.

K₃Rh₂Br₉ and K₂IrCl₆ were added to the emulsion until a concentration of 10⁻⁷ mole/mole of silver to dope silver bromide particles with Rh and Ir ions. After the addition of Na₂PdCl₄ to the emulsion, its gold and sulfur sensitization was performed by using chloroauric acid and sodium thiosulfate and it was applied to a support of polyethylene terephthalate (PET) with a gelatin hardener until a silver coating weight of 1 g/m². Silver and gelatin had a volume ratio of ½.

The PET support had a thickness of 90 μm and a width of 30 cm. The PET support having a width of 30 cm was coated with a layer having a width of 25 cm at a rate of 20 m/min. and had two 3 cm-wide edge portions cut off to leave a 24 cm-wide central portion of the coating and thereby make a roll of a silver halide photosensitive material.

(Exposure)

The exposure of the silver halide photosensitive material was performed by a continuous exposure apparatus including exposure heads having DMD (digital mirror devices) as described in Official Gazette JP-A-2004-1244 and arranged to make a total width of 25 cm, the exposure heads and stages being curved to form an image of laser light on the photosensitive layer of the photosensitive material, the apparatus being bent to have a buffer action so that the tension control of the exposed surface and variation in the speed of the take-up or feed mechanism may not affect the speed of the exposing portion. The exposure was performed with a wavelength of 400 nm, a substantially square beam measuring 12 μm square and a laser light source having an output of 100 μJ.

The exposure was so performed that grid patterns having a line width of 12 μm might have an angle of 45 deg. and continue along a width of 24 cm and a length of 10 m with a pitch of 300 μm. A copper pattern formed by plating as will be described below was found to have a line width of 12 μm and a pitch of 300 microns.

(Development)

Composition of 1 liter of developer (also of replenishing solution):

| Hydroquinone | 21 g |
|---|---|
| Sodium sulfite | 50 g |
| Potassium carbonate | 40 g |
| Ethylenediaminetetraacetic acid | 2 g |
| Potassium bromide | 3 g |
| Polyethylene glycol 2000 | 1 g |
| Potassium hydroxide | 4 g |
| pH adjusted to | 10.3 |

Composition of 1 liter of fixing solution (also of replenishing solution):

| | | |
|---|---|---|
| Ammonium thiosulfate solution (75%) | 300 | ml |
| Ammonium sulfite monohydrate | 25 | g |
| 1,3-diaminopropanetetraacetic acid | 8 | g |
| Acetic acid | 5 | g |
| Aqueous ammonia (27%) | 1 | g |

| | |
|---|---|
| pH adjusted to | 6.2 |

The exposed silver halide photosensitive material was subjected to 30 seconds of developing treatment at 30° C., 2.3 seconds of fixing treatment at 30° C. and 20 seconds of rinsing by water (5 L/min) flowing at a rate of 640 ml/m² by employing the agents shown above and an automatic developing machine, FG-710PTS, of Fuji Photo Film Company.

The treatment of the sensitive material was continued for three days at a rate of 100 m²/day by replenishing the developer at a rate of 500 ml/m² and the fixing solution at a rate of 640 ml/m².

As a result, there was produced a film having a grid-like silver-mesh pattern formed on a transparent film. The film had a surface resistance of 48.57 ohms per square.

(Plating)

The film having a silver-mesh pattern formed as described above was plated by employing an electroplating apparatus having an electroplating tank 10 as shown in FIG. 1. The film was so set in the electroplating apparatus as to have its silver-mesh pattern face downward and contact the current feed rollers.

The current feed rollers 12a and 12b were each a stainless steel roller having a diameter of 10 cm and a length of 70 cm and having a mirror surface coated with an electroplated copper layer having a thickness of 0.1 mm and the other rollers including the guide rollers 14 were each a roller having a diameter of 5 cm and a length of 70 cm and having a surface not plated with copper. The guide rollers 14 were adjustable in height so that a fixed length of dwell time might be maintained for the treatment of the film in the solution irrespective of the line speed.

The lowest boundary of contact between the inlet current feed roller 12a and the silver-mesh surface of the film and the surface of the plating solution had a distance (La in FIG. 1) of 9 cm therebetween. The lowest boundary of contact between the outlet current feed roller 12b and the silver-mesh portion of the photosensitive material and the surface of the plating solution had a distance (Lb in FIG. 1) of 19 cm therebetween. A line travel speed of 1.8 m/min. was employed.

The following is a summary of the composition of the plating solution employed, the time for dip treatment (dwell time in the solution) in each bath and the voltage applied to each plating bath. All of the solution and rinsing water employed had a temperature of 25° C. Composition of copper electroplating solution (also of replenishing solution):

| Copper sulfate pentahydrate | See Table 1 below. | |
|---|---|---|
| Sulfuric acid (97%) | 90 | g |
| Hydrochloric acid (35%) | 0.06 | ml |

| | |
|---|---|
| Bis-(sulfopropyl) disulfide | See Table 1. |
| Janus Green B (*1) | See Table 1. |
| Polyethylene glycol having an average | See Table 1. |
| molecular weight of 4,000 (*2) | |

Pure water was added until one liter.
((*1) & (*2) - Products of Wako Junyaku Kogyo)

Dwell time in plating bath and voltage applied thereto:

| | | | |
|---|---|---|---|
| Acid cleansing | 30 | sec. | |
| Water rinsing | 1 | min. | |
| Plating bath 1 | 20 | sec. | Voltage 40 V |
| Water rinsing | 30 | sec. | |
| Plating bath 2 | 20 | sec. | Voltage 40 V |
| Water rinsing | 30 | sec. | |
| Plating bath 3 | 20 | sec. | Voltage 35 V |
| Water rinsing | 30 | sec. | |
| Plating bath 4 | 20 | sec. | Voltage 35 V |
| Water rinsing | 1 | min. | |
| Plating bath 5 | 20 | sec. | Voltage 20 V |
| Water rinsing | 1 | min. | |
| Plating bath 6 | 20 | sec. | Voltage 20 V |
| Water rinsing | 1 | min. | |
| Plating bath 7 | 20 | sec. | Voltage 15 V |
| Water rinsing | 30 | sec. | |
| Plating bath 8 | 20 | sec. | Voltage 10 V |
| Water rinsing | 30 | sec. | |
| Plating bath 9 | 20 | sec. | Voltage 10 V |
| Water rinsing | 30 | sec. | |
| Plating bath 10 | 20 | sec. | Voltage 8 V |
| Water rinsing | 1 | min. | |
| Plating bath 11 | 20 | sec. | Voltage 6 V |
| Water rinsing | 1 | min. | |
| Plating bath 12 | 20 | sec. | Voltage 6 V |
| Water rinsing | 1 | min. | |
| Plating bath 13 | 20 | sec. | Voltage 5 V |
| Water rinsing | 30 | sec. | |
| Plating bath 14 | 20 | sec. | Voltage 5 V |
| Water rinsing | 1 | min. | |
| Plating bath 15 | 20 | sec. | Voltage 3 V |
| Water rinsing | 1 | min. | |
| Plating bath 16 | 20 | sec. | Voltage 2 V |
| Water rinsing | 1 | min. | |
| Plating bath 17 | 20 | sec. | Voltage 1 V |
| Water rinsing | 1 | min. | |
| Rust-proofing | 20 | sec. | |
| Water rinsing | 1 | min. | |

(Evaluation)

Several film samples each having a length of 10 m were examined for the surface resistance of their plated mesh surfaces. Their surface resistance was determined by measuring the surface resistance at arbitrarily selected 50 points of the film excluding its leading and trailing end portions each having a length of 50 cm by an instrument of DIA INSTRUMENTS CO., Loresta-GP (Model MCP-T610) with a serial 4-pin probe (ASP), and calculating the average of the results. The surface resistance of each sample was as shown in Table 2.

Each sample was also visually inspected for plating unevenness. The evaluation as to plating unevenness was made in accordance with the following criteria:

1: Hardly any unevenness was perceived.

2: Unevenness was found in less than 15% of the area.

3: Unevenness was found in from 15% to less than 30% e whole area.

4: Unevenness was found in from 30% to less than 80% e whole area.

5: Unevenness was found in 80% or more of the whole

TABLE 1

| | Concentration of | Concentration of | | | |
|---|---|---|---|---|---|
| | copper sulfate | bis-(sulfopropyl) | Concentration of | Concentration of | |
| Sample | pentahydrate | disulfide | Janus Green B | polyethylene | |
| No. | (g/l) | (mg/l) | (mg/l) | glycol (mg/l) | Remarks |
| 101 | 130 | — | — | — | Comparative |
| 102 | 160 | — | — | — | Invention |
| 103 | 200 | — | — | — | Invention |
| 104 | 270 | — | — | — | Invention |
| 105 | 200 | 22 | — | — | Invention |
| 106 | 200 | 22 | 20 | — | Invention |
| 107 | 200 | 22 | 20 | 180 | Invention |

| | | |
|---|---|---|
| 108 | Not treated | Reference |

TABLE 2

| | Surface | | |
|---|---|---|---|
| Sample | resistance | Plating | |
| No. | (Ω/sq.) | unevenness | Remarks |
| 101 | 10.80 | 5 | Comparative |
| 102 | 0.55 | 3 | Invention |
| 103 | 0.35 | 2 | Invention |
| 104 | 0.46 | 3 | Invention |
| 105 | 0.29 | 1 | Invention |
| 106 | 0.24 | 1 | Invention |
| 107 | 0.21 | 1 | Invention |
| 108 | 48.57 | — | Reference |

### Example 2

A sample having a surface resistance of 50 ohms per square was prepared by effecting copper sputtering on a PET support and otherwise repeating Example 1 and was plated under the same conditions as in Example 1 with the same plating solution as used for Sample 107. The plated sample showed a surface resistance of 0.37 and level 2 of planting unevenness. Thus, the film having a silver mesh according to Example 1 was found preferable.

### Example 3

A sample having a width of 67 cm instead of 24 cm was prepared and plated by repeating Example 1. There were obtained results similar to those of Example 1.

### Example 4

The copper surface of Sample 105 of Example 1 was blackened by treating with a copper blackening solution. A commercially available product, Copper Black, of K.K. Isolate Kagaku Kenkyujo was employed as the blackening solution.

A protective film having a total thickness of 28 μm (Product No. HT-25 of PANAC KOGYO K.K.) was stuck to the opposite side of the PET support from the metal mesh by mens of a laminator roller. A protective film made by laminating an acrylic adhesive layer on a polyethylene film and having a total thickness of 65 μm (Product SANITECT Y-26F of K.K. SANEI KAKEN) was stuck to the metal mesh side of the support by means of a laminator roller.

Then, a glass sheet measuring 2.5 mm thick by 950 mm by 550 mm was stuck to the opposite side of the PET support from the metal mesh by a transparent acrylic adhesive.

Then, an antireflective near-infrared absorbing film (Product CLEARAS AR/NIR of Sumitomo Osaka Cement Co., Ltd.) formed from a PET film having a thickness of 100 μm, an antireflective layer and a layer containing a near-infrared absorber was stuck to the inner part of the metal mesh excluding an outer edge portion having a width of 20 mm by a light-transmitting acrylic adhesive layer having a thickness of 25 μm. The light-transmitting acrylic adhesive layer contained toning pigments (PS-Red-G and PS-Violet-RC of Mitsui Kagaku) for controlling the transmission properties of an optical filter.

Then, an antireflective film (Product REALOOK 8201 of NOF CORP.) was stuck to the glass sheet by an adhesive to make an optical filter.

The optical filter was a product of very few scratches and metal-mesh defects, since it had been formed from an electromagnetic wave shielding film having a protective film. As the metal mesh had a black color, the optical filter did not give any metallic color to any image on a display, but showed a practically satisfactory electromagnetic wave shielding power and a near-infrared blocking power allowing the transmission of only 15% or less of radiation having a wavelength of 300 to 800 nm and the antireflective layers formed on both sides thereof made it possible to realize a display having a high level of visibility. Moreover, the pigments gave the filter a toning function making it suitable as an optical filter for a plasma display, etc.

### INDUSTRIAL APPLICABILITY

The plating method of the present invention makes it possible to plate the whole surface of a film uniformly and efficiently by electroplating and provide a uniformly plated light-transmitting electrically conductive film of high productivity and a light-transmitting electromagnetic wave shielding film formed therefrom.

The entire disclosure of each and every foreign patent application from which the benefit of foreign priority has been claimed in the present application is incorporated herein by reference, as if fully set forth.

1. A plating method comprising:
continuously electroplating a film having a surface resistance of 1 to 1,000 ohms per square with a plating solution,
wherein a plating solution has a copper content of 150 to 300 g/l as expressed by weight of copper sulfate pentahydrate.

2. The plating method according to claim 1,
wherein the plating solution comprises a sulfur compound.

3. The plating method according to claim 1,
wherein the plating solution comprises a nitrogen compound.

4. The plating method according to claim 1,
wherein the plating solution comprises a polymer.

5. The plating method according to claim 1,
wherein the film has a pattern formed with a silver mesh.

6. The plating method according to claim 5,
wherein the silver mesh is formed from a developed silver.

7. The electrically conductive film produced by a method including a
plating method according to claim 1.

8. A light-transmitting electromagnetic wave shielding film comprising an electrically conductive film according to claim 7.

9. An optical filter comprising:
a light-transmitting electromagnetic wave shielding film according to claim 8; and
an adhesive layer.

10. The optical filter according to claim 9, which further comprises a peelable protective film.

11. The optical filter according to claim 9, which further comprises a functional layer having at least one function selected from infrared blocking, hard coating, antireflective, antiglare, antistatic, anti-staining, ultraviolet blocking, gas barrier and display panel damage preventing.

12. The optical filter according to claim 9, which has an infrared blocking property.

13. The plating method according to claim 5, wherein the film having the silver mesh pattern is formed by exposing and developing a photosensitive material having an emulsion layer containing a silver salt emulsion on a support.

14. The plating method according to claim 4, wherein the polymer is polyethylene glycol.

15. The plating method according to claim 1, wherein the film is conveyed at a speed of 1 to 30 m/min.

16. The plating method according to claim 1, which further comprises: conducting a water and acid cleansing before electroplating the film.

17. A method for producing an electrically conductive film, comprising:
continuously electroplating a film having a surface resistance of 1 to 1,000 ohms per square with a plating solution,
wherein the plating solution has a cooper content of 150 to 300 g/l as expressed by weight of copper sulfate pentahydrate.

18. A method for producing an electrically conductive film, comprising:
forming a silver mesh by exposing and developing a photosensitive material having an emulsion layer containing a silver salt emulsion on a support; and
subjecting a film having the formed silver mesh to a plating treatment with a plating solution having a copper content of 150 to 300 g/l as expressed by weight of copper sulfate pentahydrate.

19. A method for producing an electrically conductive film, comprising:
conveying an elongate film having a pattern formed with a silver mesh to an electroplating tank; and
continuously electroplating the elongate film with a plating solution having a copper content of 150 to 300 g/l as expressed by weight of copper sulfate pentahydrate to form an electrically conductive metal film on the silver mesh.
